(19) United States
(12) Patent Application Publication
(10) Pub. No.: US 2026/0293362 A1
(43) Pub. Date: Sep. 24, 2026

(54) Packaging Method for Photoelectric Element

(71) Applicant: National Atomic Research Institute, Taoyuan (TW)

(72) Inventors: Yueh-Mu Lee, Taoyuan (TW); Yu-Li Tsai, Taoyuan (TW); Kai-Hsiang Yang, Taoyuan (TW); Chia-Wei Lin, Taoyuan (TW); Chun-Yi Chen, Taoyuan (TW)

(21) Appl. No.: 19/452,526

(22) Filed: Jan. 19, 2026

(30) Foreign Application Priority Data
Mar. 18, 2025 (TW) 114110144

(51) Int. Cl. H10F 71/00; H10F 77/00; H10F 77/50

(52) U.S. Cl. CPC H10F 71/127; H10F 77/50; H10F 77/939

(57) ABSTRACT

A packaging method for a photoelectric element is configured for direct immersion of a solar cell in an acid/alkaline electrolyte. The resulting packaging structure allows the solar cell to be resistant to etching and structural damage resulting from the acid/alkaline electrolyte during a hydrogen/oxygen production process. In addition to protecting the solar cell without shielding incident light, the method transfers electrons and holes through a circuit to expand a contact area with the electrolyte, significantly improving durability and lifespan. Furthermore, the method increases photocurrent to enhance hydrogen/oxygen production efficiency, maximizing the lifespan and hydrogen/oxygen production efficiency of the solar cell while further significantly reducing costs.

### FIELD OF THE INVENTION

The present invention relates to a packaging method for a photoelectric element, particularly to a packaging method enabling direct immersion of a solar cell in an acid/alkaline electrolyte, and more particularly to a method where the structure of the solar cell is resistant to etching and damage resulting from the acid/alkaline electrolyte during the hydrogen/oxygen production process.

### DESCRIPTION OF THE PRIOR ART

Primary sources of hydrogen energy in Taiwan include catalytic decomposition of fossil fuels, recovery of industrial byproducts, and production of green hydrogen via renewable-energy-driven water electrolysis. Given Taiwan's active promotion of renewable energy development, the utilization of surplus renewable electricity for hydrogen gas production holds significant future potential.

Conventional water electrolysis for hydrogen production requires an external power supply to provide electrical energy, with the electrolysis reaction occurring at the electrode surfaces. By contrast, photoelectrochemical (PEC) water splitting leverages light energy to directly excite charge carriers (electrons and holes) within a semiconductor material, thereby catalyzing water dissociation into hydrogen gas and oxygen gas. While such direct immersion simplifies system architecture and reduces energy conversion losses—thus enhancing overall efficiency—mitigating corrosion and structural degradation of solar cells during prolonged exposure to acid/alkaline electrolytes remains a critical technical challenge. Furthermore, conventional techniques exhibit the following drawbacks:
1. Limited hydrogen/oxygen production area: To prevent electrical short-circuiting between the positive and negative electrodes of a solar cell 6 resulting from electrolyte contact, conventional techniques involve coating a peripheral bead of insulating glue 61 around the solar cell 6 (as shown in FIG. 10). The coverage of this insulating glue extends to a portion of the front surface of the solar cell 6, thereby restricting the effective reaction area between the solar cell 6 and the electrolyte. Furthermore, as the hydrogen production reaction occurs at the solar cell surface (where A denotes a hydrogen production zone and B denotes an oxygen production zone), the resultant hydrogen bubbles impede incident light and interfere with electrolyte contact, thereby diminishing hydrogen production efficiency.
2. Constraints in optimizing ohmic contact metals: Typically, to enhance hydrogen/oxygen conversion efficiency, specific photocatalytic materials, such as platinum (Pt) or rhodium (Rh), are deposited onto the surface of a solar cell. However, these materials do not readily form high-quality ohmic contacts with solar cells; even after thermal annealing, the interfacial impedance remains elevated. Furthermore, such materials obscure the solar cell and impede light absorption, frequently leading to a degradation of the solar cell's electrical efficiency.
3. Suboptimal light utilization: In conventional techniques, the solar cell is subject to shadowing by the surface photocatalyst thin film and the bubbles generated from the hydrogen production reaction, which collectively hinder the solar cell's light reception.

In view of the aforementioned deficiencies in conventional techniques, there is an urgent need for an invention capable of concurrently addressing the susceptibility of solar cells to corrosive damage from acid/alkaline electrolytes while overcoming the technical shortcomings of the related art.

### BRIEF SUMMARY OF THE INVENTION

Therefore, the main purpose of the present invention is to overcome the aforementioned problems encountered in the prior art and provide a packaging method enabling direct immersion of a solar cell in an acid/alkaline electrolyte. The structure of the solar cell is resistant to etching and damage resulting from the acid/alkaline electrolyte during the hydrogen/oxygen production process, significantly improving durability and lifespan. Additionally, the method increases photocurrent to enhance hydrogen/oxygen production efficiency, and through the aforementioned advantages, the packaging method for a photoelectric element can significantly reduce costs.

Another purpose of the present invention is to provide a packaging structure that can protect the solar cell without shielding incident light and transfers electrons and holes through a circuit to expand the contact area with the electrolyte, maximizing the lifespan and hydrogen/oxygen production efficiency of the solar cell while further reducing costs.

To achieve the above purposes, the present invention is a packaging method for a photoelectric element, comprising: step 1: adhering a solar cell chip having positive and back electrodes to a front surface of a carrier board using a conductive paste, wherein the carrier board includes an insulating layer having a front surface provided with a first metal layer and a second metal layer and a back surface provided with a third metal layer, the first metal layer being electrically connected to the back electrode of the solar cell chip, and the second metal layer being electrically connected to the third metal layer through a through-hole in the insulating layer, such that the first metal layer and the second metal layer form a first patterned conductive circuit, and the third metal layer forms a second patterned conductive circuit; step 2: welding at least one gold wire using a wire bonder to electrically connect the solar cell chip to the second metal layer via the at least one gold wire; step 3: coating optical-grade silicone on the solar cell chip and surroundings thereof to form an insulating protective layer covering the second metal layer, the solar cell chip, and a portion of the first metal layer; and step 4: depositing a photocatalyst effective for catalyzing a hydrogen or oxygen production reaction respectively on a portion of the first metal layer on the front surface of the carrier board that is exposed by the insulating protective layer and on the third metal layer on the back surface of the carrier board, thereby completing a packaging structure of a solar cell configured for direct immersion in an electrolyte.

In the above embodiments of the present invention, the solar cell chip comprises a III-V semiconductor material, a metal oxide material, or a nitrogen compound material.

In the above embodiments of the present invention, the III-V semiconductor material may be selected from indium gallium phosphide (InGaP), gallium arsenide (GaAs), indium phosphide (InP), or any combination thereof.

In the above embodiments of the present invention, the metal oxide material may be selected from titanium dioxide (TiO₂), tungsten trioxide (WO₃), copper dioxide (CuO₂), ferric oxide (Fe₂O₃), bismuth vanadate (BiVO₄), or any combination thereof.

In the above embodiments of the present invention, the nitrogen compound material may be selected from boron carbon nitride (BCN), carbon nitride (C₃N₄), indium nitride (InN), indium gallium nitride (InGaN), gallium nitride (GaN), or any combination thereof.

In the above embodiments of the present invention, the insulating layer may be selected from aluminum oxide (Al₂O₃), aluminum nitride (AlN), silicon dioxide (SiO₂), beryllium oxide (BeO), silicon nitride (Si₃N₄), boron nitride (BN), or any combination thereof.

In the above embodiments of the present invention, the photocatalyst may be selected from platinum (Pt), rhodium (Rh), nickel (Ni), iridium oxide (IrOx), nickel-molybdenum (NiMo), cobalt (II, III) oxide (Co₃O₄), chromium (III) oxide (Cr₂O₃), or any combination thereof.

In the above embodiments of the present invention, the electrolyte may be sulfuric acid (H₂SO₄), potassium hydroxide (KOH), potassium phosphate buffer, or water.

In the above embodiments of the present invention, the conductive paste may be solder paste, silver paste, or copper paste.

### BRIEF DESCRIPTION OF THE DRAWINGS

The present invention will be better understood from the following detailed description of preferred embodiments of the invention, taken in conjunction with the accompanying drawings, in which

FIG. 1 is a schematic flow chart of a packaging process for a photoelectric element of the present invention;

FIG. 2 is a schematic side view of adhering a solar cell chip to a front surface of a carrier board of the present invention;

FIG. 3 is a schematic top view of adhering the solar cell chip to the front surface of the carrier board of the present invention;

FIG. 4 is a schematic side view of welding a gold wire of the present invention;

FIG. 5 is a schematic top view of welding the gold wire of the present invention;

FIG. 6 is a schematic side view of coating optical-grade silicone of the present invention;

FIG. 7 is a schematic top view of coating the optical-grade silicone of the present invention;

FIG. 8 is a schematic side view of plating a photocatalyst of the present invention;

FIG. 9 is a schematic top view of plating the photocatalyst of the present invention; and

FIG. 10 (PRIOR ART) is a schematic structural diagram of a solar cell package in accordance with conventional technology.

### DESCRIPTION OF THE PREFERRED EMBODIMENTS

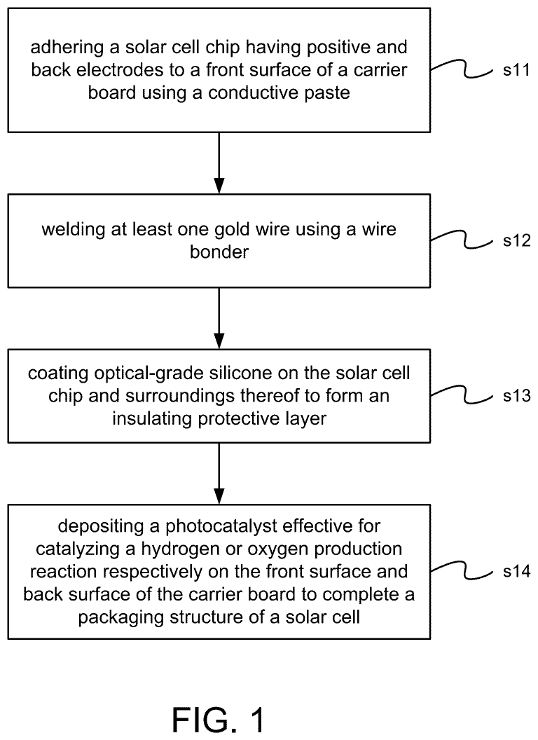

The following descriptions of the preferred embodiments are illustrated in FIGS. 1-9 and provided to understand the features and the structures of the present invention.

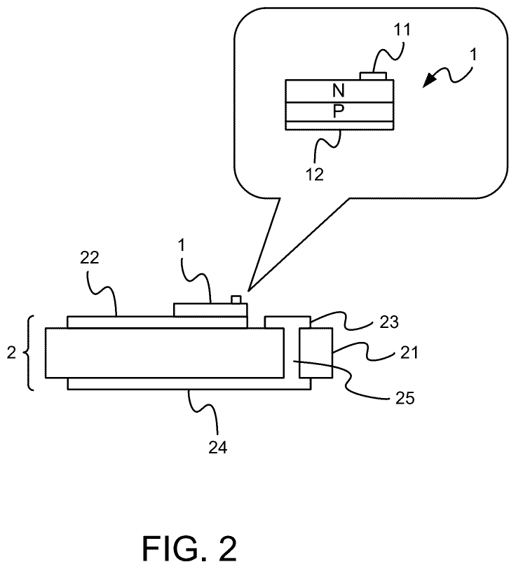

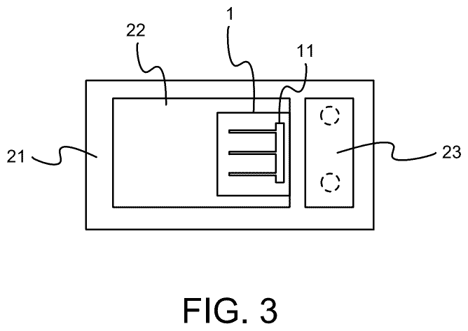

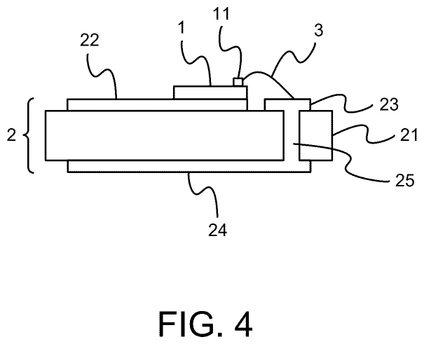

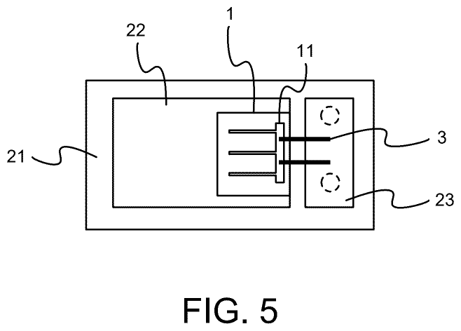

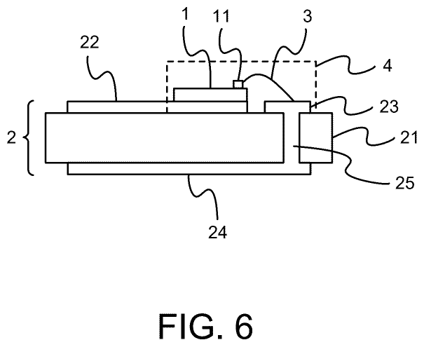

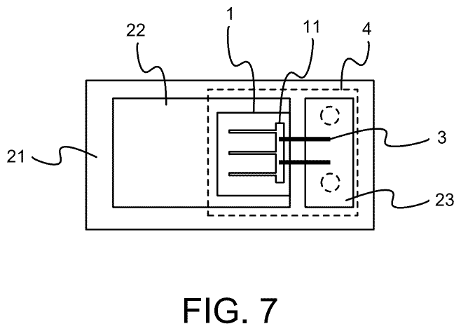

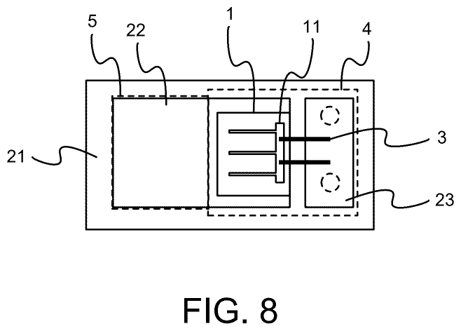

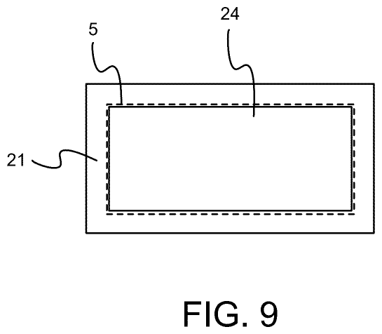

FIG. 1 is a schematic flow chart of a packaging process for a photoelectric element of the present invention. FIG. 2 is a schematic side view of adhering a solar cell chip to a front surface of a carrier board of the present invention. FIG. 3 is a schematic top view of adhering the solar cell chip to the front surface of the carrier board of the present invention. FIG. 4 is a schematic side view of welding a gold wire of the present invention. FIG. 5 is a schematic top view of welding the gold wire of the present invention. FIG. 6 is a schematic side view of coating optical-grade silicone of the present invention. FIG. 7 is a schematic top view of coating the optical-grade silicone of the present invention. FIG. 8 is a schematic side view of plating a photocatalyst of the present invention. FIG. 9 is a schematic top view of plating the photocatalyst of the present invention. As shown in the figures, the present invention is a packaging method for a photoelectric element. The resulting packaging structure can protect the solar cell without shielding incident light and transfers electrons and holes through a circuit to expand the contact area with the electrolyte, maximizing the lifespan and hydrogen/oxygen production efficiency of the solar cell while further reducing costs. The implementation thereof at least includes the following steps:
Step 1: adhering a solar cell chip 1 having positive and back electrodes 11, 12 to a front surface of a carrier board 2 using a conductive paste, with the carrier board 2 including an insulating layer 21 that has a front surface provided with a first metal layer 22 and a second metal layer 23 and a back surface provided with a third metal layer 24, the first metal layer 22 being electrically connected to the back electrode 11 of the solar cell chip 1, and the second metal layer 23 being electrically connected to the third metal layer 24 through a through-hole 25 in the insulating layer 21, such that the first metal layer 22 and the second metal layer 23 form a first patterned conductive circuit, and the third metal layer 24 forms a second patterned conductive circuit, as shown in FIGS. 2 and 3;
Step 2: welding at least one gold wire 3 using a wire bonder to electrically connect the solar cell chip 1 to the second metal layer 23 via the at least one gold wire 3, as shown in FIGS. 4 and 5;
Step 3: coating optical-grade silicone on the solar cell chip 1 and surroundings thereof to form an insulating protective layer 4 covering the second metal layer 23, the solar cell chip 1, and a portion of the first metal layer 22, as shown in FIGS. 6 and 7;
Step 4: depositing a photocatalyst 5 (as indicated by the dashed boxes in FIGS. 8 and 9) effective for catalyzing a hydrogen or oxygen production reaction respectively on a portion of the first metal layer 22 on the front surface of the carrier board 2 that is exposed by the insulating protective layer 4 and on the third metal layer 24 on the back surface of the carrier board 2, thereby completing a packaging structure of a solar cell 100 configured for direct immersion in an electrolyte. Thus, the disclosed process constitutes a brand-new packaging method for a photoelectric element.

In a preferred embodiment of the present invention, the solar cell chip 1 may be made of a III-V semiconductor material selected from indium gallium phosphide (InGaP), gallium arsenide (GaAs), indium phosphide (InP), or any combination thereof.

In a preferred embodiment of the present invention, the solar cell chip 1 may be made of a metal oxide material selected from titanium dioxide (TiO₂), tungsten trioxide (WO₃), copper dioxide (CuO₂), ferric oxide (Fe₂O₃), bismuth vanadate (BiVO₄), or any combination thereof.

In a preferred embodiment of the present invention, the solar cell chip 1 may be made of a nitrogen compound material selected from boron carbon nitride (BCN), carbon nitride (C₃N₄), indium nitride (InN), indium gallium nitride (InGaN), gallium nitride (GaN), or any combination thereof.

In a preferred embodiment of the present invention, the insulating layer 21 of the carrier board 2 may be made of an insulating and acid/alkaline-resistant material selected from aluminum oxide (Al₂O₃), aluminum nitride (AlN), silicon dioxide (SiO₂), beryllium oxide (BeO), silicon nitride (Si₃N₄), boron nitride (BN), or any combination thereof.

In a preferred embodiment of the present invention, the photocatalyst 5 may be selected from platinum (Pt), rhodium (Rh), nickel (Ni), iridium oxide (IrOx), nickel-molybdenum (NiMo), cobalt (II, III) oxide (Co₃O₄), chromium (III) oxide (Cr₂O₃), or any combination thereof.

In a preferred embodiment of the present invention, the electrolyte may be sulfuric acid (H₂SO₄), potassium hydroxide (KOH), potassium phosphate buffer, or water.

In a preferred embodiment of the present invention, the conductive paste may be solder paste, silver paste, or copper paste.

Therefore, the present invention has advantages as follows:

### 1. Increased Hydrogen/Oxygen Production Area

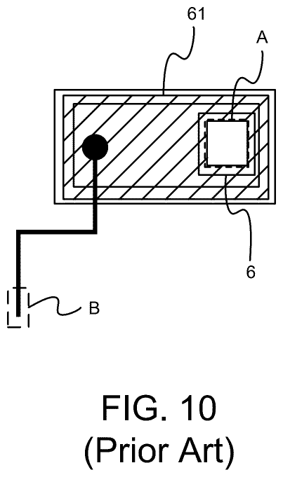

Compared with the conventional techniques that involve coating a peripheral bead of insulating glue around a solar cell as illustrated in FIG. 10, the present invention discloses transferring electrons and holes generated as a result of illumination of a solar cell to metal layers on the front and back surfaces of a carrier board to significantly increase hydrogen/oxygen production contact area. Since the reaction zone is not located on the surface of the solar cell, light absorption is unobstructed, allowing the solar cell to maintain an optimal operating state. Furthermore, both the metal layers on the front and back surfaces of the carrier board can be coated with a photocatalyst material and a corrosion-resistant material without selection constraints (whereas conventional techniques require considering shielding effects and interfacial impedance if applied to the solar cell surface), thereby significantly enhancing durability and the hydrogen/oxygen production reaction, as illustrated in FIGS. 8 and 9.

### 2. Preferred Ohmic Contact Metals Can be Selected

The present invention is capable of utilizing commonly used electrode metals (for example, selecting metals such as nickel (Ni), germanium (Ge), gold (Au), and palladium (Pd) for n-GaAs) to achieve lower metal-semiconductor interfacial impedance and maintain optimal electrical properties.

### 3. Optimizing Light Utilization

The optical-grade silicone coated on the solar cell of the present invention is fully transparent and does not obstruct incident light. In addition to protecting the solar cell from corrosion by the acid/alkaline electrolyte, the silicone coating provides a micro-concentrating effect that can enhance the photocurrent by at least 5%, effectively improving the efficiency of the solar cell and increasing the volume of hydrogen/oxygen production.

In summary, the present invention is a packaging method for a photoelectric element that effectively overcomes the various drawbacks of conventional techniques. By providing a packaging approach that allows for the direct immersion of a solar cell in an acid/alkaline electrolyte, the structure of the solar cell is resistant to etching and damage by the acid/alkaline electrolyte during the hydrogen/oxygen production process, thereby significantly improving durability and service life. Furthermore, the present invention increases photocurrent and enhances hydrogen/oxygen production efficiency. These advantages substantially reduce costs, rendering the present invention more advanced, practical, and aligned with user requirements. As the present invention meets the requirements for patentability, a patent application is hereby filed.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A packaging method for a photoelectric element, comprising:
step 1: adhering a solar cell chip having positive and back electrodes to a front surface of a carrier board using a conductive paste, wherein the carrier board includes an insulating layer having a front surface provided with a first metal layer and a second metal layer and a back surface provided with a third metal layer, the first metal layer being electrically connected to the back electrode of the solar cell chip, and the second metal layer being electrically connected to the third metal layer through a through-hole in the insulating layer, such that the first metal layer and the second metal layer form a first patterned conductive circuit, and the third metal layer forms a second patterned conductive circuit;
step 2: welding at least one gold wire using a wire bonder to electrically connect the solar cell chip to the second metal layer via the at least one gold wire;
step 3: coating optical-grade silicone on the solar cell chip and surroundings thereof to form an insulating protective layer covering the second metal layer, the solar cell chip, and a portion of the first metal layer; and
step 4: depositing a photocatalyst effective for catalyzing a hydrogen or oxygen production reaction respectively on a portion of the first metal layer on the front surface of the carrier board that is exposed by the insulating protective layer and on the third metal layer on the back surface of the carrier board, thereby completing a packaging structure of a solar cell configured for direct immersion in an electrolyte.

2. The packaging method for a photoelectric element according to claim 1, wherein the solar cell chip comprises a III-V semiconductor material, a metal oxide material, or a nitrogen compound material.

3. The packaging method for a photoelectric element according to claim 2, wherein the III-V semiconductor material may be selected from indium gallium phosphide (InGaP), gallium arsenide (GaAs), indium phosphide (InP), or any combination thereof.

4. The packaging method for a photoelectric element according to claim 2, wherein the metal oxide material may be selected from titanium dioxide (TiO₂), tungsten trioxide (WO₃), copper dioxide (CuO₂), ferric oxide (Fe₂O₃), bismuth vanadate (BiVO₄), or any combination thereof.

5. The packaging method for a photoelectric element according to claim 2, wherein the nitrogen compound material may be selected from boron carbon nitride (BCN), carbon nitride (C₃N₄), indium nitride (InN), indium gallium nitride (InGaN), gallium nitride (GaN), or any combination thereof.

6. The packaging method for a photoelectric element according to claim 1, wherein the insulating layer may be selected from aluminum oxide (Al₂O₃), aluminum nitride (AlN), silicon dioxide (SiO₂), beryllium oxide (BeO), silicon nitride (Si₃N₄), boron nitride (BN), or any combination thereof.

7. The packaging method for a photoelectric element according to claim 1, wherein the photocatalyst may be selected from platinum (Pt), rhodium (Rh), nickel (Ni), iridium oxide (IrOx), nickel-molybdenum (NiMo), cobalt (II, III) oxide (Co₃O₄), chromium (III) oxide (Cr₂O₃), or any combination thereof.

8. The packaging method for a photoelectric element according to claim 1, wherein the electrolyte may be sulfuric acid (H₂SO₄), potassium hydroxide (KOH), potassium phosphate buffer, or water.

9. The packaging method for a photoelectric element according to claim 1, wherein the conductive paste may be solder paste, silver paste, or copper paste.
